(19) United States
(12) Patent Application Publication
(10) Pub. No.: US 2008/0258170 A1
(43) Pub. Date: Oct. 23, 2008

(54) Light emitting diode structure

(75) Inventor: Chin-Yuan Hsu, Kaohsiung City (TW)

Correspondence Address: RAYMOND R. MOSER JR., ESQ.;MOSER IP LAW GROUP, 1030 BROAD STREET, 2ND FLOOR, SHREWSBURY, NJ, 07702, US

(73) Assignee: Everlight Electronics Co., Ltd.

(21) Appl. No.: 12/008,199

(22) Filed: Jan. 9, 2008

(30) Foreign Application Priority Data
Apr. 20, 2007 (TW) 96114089

(51) Int. Cl. H01L 33/00

(52) U.S. Cl. 257/99; 257/E33.059

(57) ABSTRACT

The light emitting diode structure includes a substrate, a first electricity semiconductor layer formed on the substrate, a light-emitting layer formed on the first electricity semiconductor layer, a second electricity semiconductor layer formed on the light-emitting layer, a barrier layer formed on the second electricity semiconductor layer, and a contact layer formed on the barrier layer.

### RELATED APPLICATIONS

This application claims priority to Taiwan Application Serial Number 96114089, filed Apr. 20, 2007, which is herein incorporated by reference.

### BACKGROUND

1. Field of Invention

The present invention relates to a light emitting diode structure. More particularly, the present invention relates to a light emitting structure having a barrier layer.

2. Description of Related Art

Semiconductor light emitting diode (LED) has become a promising device for general-purpose illumination applications. LED has the features of excellent durability, long operation life, low power consumption, containing no mercury and potentially high efficiency. LED is an illumination light source that is good for environmental protection and energy saving. The conventional illumination devices such as incandescent bulbs are cheap in price, but, unfortunately, they have drawbacks of low efficiency, high power consumption, short operation life and fragility. The fluorescent lamps are energy saving devices but still fragile, and contain mercury causing environmental pollution problems. Therefore, the LEDs are ideal light sources for general-purpose illumination applications of new generation.

In a conventional LED device, a contact layer or a metal electrode is usually formed on a semiconductor material of an epitaxy structure to generate the conductive LED device. However, a reaction, a phase transformation, or a diffusion between the semiconductor and the metal layer may be generated when the LEDs work under high temperature or high power, and the life or the reliability of the LEDs would be reduced.

For the forgoing reasons, there is a need for preventing the reaction between the semiconductor material and the metal layer.

### SUMMARY

The invention provides a light emitting diode structure. The light emitting diode structure includes a substrate, a first electricity semiconductor layer formed on the substrate, a light-emitting layer formed on the first electricity semiconductor layer, a second electricity semiconductor layer formed on the light-emitting layer, a barrier layer formed on the second electricity semiconductor layer, and a contact layer formed on the barrier layer.

In another embodiment, the light emitting diode structure includes a semiconductor laminated layers, a barrier layer formed on the semiconductor laminated layer, and a contact layer formed on the barrier layer. The semiconductor laminated layers include a N-type semiconductor layer, a P-type semiconductor layer, and a light-emitting layer disposed between the N-type semiconductor layer and the P-type semiconductor layer;

The barrier layer of the embodiment of the light emitting structure could prevent the metal atoms of the contact layer diffusing into the semiconductor laminated layers, and could also prevent the reaction or phase transformation between the contact layer and the surface of the semiconductor laminated layers. The reliability of the light emitting diode could be improved by adding the barrier layer between the contact layer and the semiconductor laminated layers.

It is to be understood that both the foregoing general description and the following detailed description are by examples, and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1 is a cross-section diagram of an embodiment of the light emitting diode structure of the invention.

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

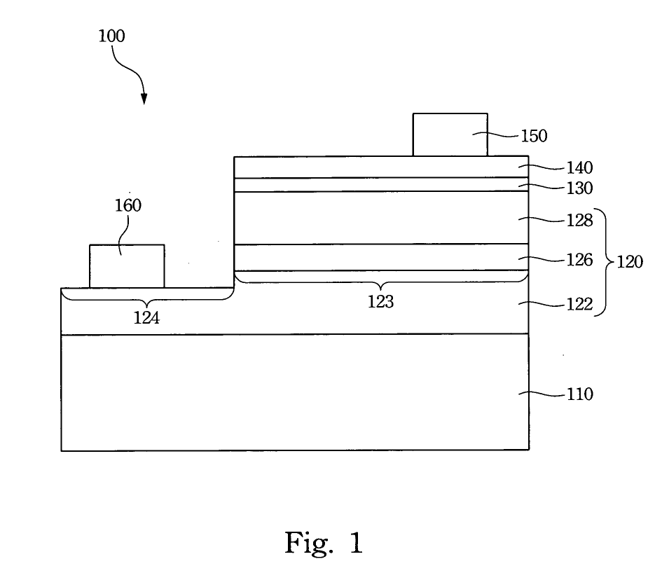

Refer to FIG. 1. FIG. 1 illustrates a cross-section view diagram of an embodiment of the light-emitting diode structure of the invention. The light-emitting diode structure 100 includes a substrate 110, a semiconductor laminated layers 120 formed on the substrate 110, a barrier layer 130 formed on the semiconductor laminated layers 120, and a contact layer 140 formed on the barrier layer 130. The contact layer 140 may be a metal layer. The barrier layer 130 of the light-emitting diode structure 100 may prevent the metal atoms of the contact layer 140 diffusing into the semiconductor laminated layers 120, and also reduce the reaction or the phase transformation between the contact layer 140 and the semiconductor laminated layers 120, that may improve the reliability of the light-emitting diode structure 100.

The material of the barrier layer 130 may be a metallic oxide, such as a gallium oxide or a nickel oxide. The material of the barrier layer 130 may be a tungsten or a tungsten alloy. The material of the barrier layer 130 may be a silicon nitrides, a boron nitrides, or a metallic nitrides, such as an aluminum nitrides. The barrier layer 130 may be formed on the surface of the semiconductor laminated layers 120 by chemical vapor deposition (CVD), physical vapor deposition (PVD), electron beam evaporation, ion sputtering, etc.

The substrate 110 of the light emitting diode structure 100 may be a silicon substrate, a silicon carbide substrate, a sapphire substrate, a gallium nitrides substrate, a aluminum nitrides substrate, or a metal substrate, such as a copper substrate or an aluminum substrate. The semiconductor laminated layers 120 include a first electricity semiconductor layer 122, a second semiconductor layer 128, and a light-emitting layer 126 between the first electricity semiconductor layer 122 and the second semiconductor layer 128. The first electricity semiconductor layer 122 is formed on the substrate. The first electricity semiconductor layer 122 and the second electricity semiconductor layer 128 have opposite electricity respectively. For example, the first electricity semiconductor layer 122 may be a N-type semiconductor layer, and the second electricity semiconductor layer 128 may be a P-type semiconductor layer. The first electricity semiconductor layer 122 may be the P-type semiconductor layer, and the second electricity semiconductor layer 128 may be the N-type semiconductor layer in another embodiment.

The first electricity semiconductor layer 122 as shown in the semiconductor laminated layers 120 may have a covered area 123 and an uncovered area 124. The semiconductor laminated layers 120 may be etched to reveal the uncovered area 124 of the first electricity semiconductor layer 122. The light-emitting layer 126, the second electricity semiconductor layer 128, the barrier layer 130, and the contact layer 140 are formed on the covered area 123 of the first electricity semiconductor layer 122. The light emitting diode structure 100 may have a first electrode 150 and a second electrode 160. The first electrode 150 and the second electrode 160 may have opposite electricity respectively. The first electrode 150 may be formed on the contact layer 140, and the second electrode 160 may be formed on the uncovered area 124 of the first electricity semiconductor layer 122.

In another embodiment (not shown), the substrate 110 may be the conductive metal substrate, and the second electrode 160 may be formed on the back side not facing the semiconductor laminated layers 120 of the substrate 110, i.e. the first electrode 150 and the second electrode 160 may be arranged vertically.

The barrier layer of the embodiment of the light emitting structure could prevent the metal atoms of the contact layer diffusing into the semiconductor laminated layers, and could also prevent the reaction or phase transformation between the contact layer and the surface of the semiconductor laminated layers. The reliability of the light emitting diode could be improved by adding the barrier layer between the contact layer and the semiconductor laminated layers.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A light emitting diode structure comprising:
a substrate;
a first electricity semiconductor layer formed on the substrate;
a light-emitting layer formed on the first electricity semiconductor layer;
a second electricity semiconductor layer formed on the light-emitting layer;
a barrier layer formed on the second electricity semiconductor layer; and
a contact layer formed on the barrier layer.

2. The light emitting diode structure of claim 1, wherein the first electricity semiconductor layer comprises a covered area and an uncovered area, and the light-emitting layer, the second electricity semiconductor layer, the barrier layer, and the contact layer are formed on the covered area.

3. The light emitting diode structure of claim 2, wherein the light-emitting diode structure comprises a first electrode and a second electrode formed on the contact layer and the uncovered area of the first electricity respectively.

4. The light emitting diode structure of claim 1, wherein a material of the barrier layer is a tungsten or a tungsten alloy.

5. The light emitting diode structure of claim 1, wherein a material of the barrier layer is a metallic oxide.

6. The light emitting diode structure of claim 5, wherein the material of the barrier layer is a gallium oxide or a nickel oxide.

7. The light emitting diode structure of claim 1, wherein a material of the barrier layer is a silicon nitrides or a boron nitrides.

8. The light emitting diode structure of claim 1, wherein a material of the barrier layer is a metallic nitrides.

9. A light emitting diode structure comprising:
a semiconductor laminated layers having a N-type semiconductor layer, a P-type semiconductor layer, and a light-emitting layer disposed between the N-type semiconductor layer and the P-type semiconductor layer;
a barrier layer formed on the semiconductor laminated layer; and
a contact layer formed on the barrier layer.

10. The light emitting diode structure of claim 9, wherein a material of the barrier layer is a tungsten or a tungsten alloy.

11. The light emitting diode structure of claim 9, wherein a material of the barrier layer is a metallic oxide.

12. The light emitting diode structure of claim 9, wherein the material of the barrier layer is a gallium oxide or a nickel oxide.

13. The light emitting diode structure of claim 9, wherein a material of the barrier layer is a silicon nitrides or a boron nitrides.

14. The light emitting diode structure of claim 9, wherein a material of the barrier layer is a metallic nitrides.
